(19) United States
(12) Patent Application Publication
(10) Pub. No.: US 2023/0052829 A1
(43) Pub. Date: Feb. 16, 2023

(54) COMPOSITIONS AND METHODS OF USE THEREOF

(71) Applicant: Fujifilm Electronic Materials U.S.A., Inc., N. Kingstown, RI (US)

(72) Inventors: Ting-Kai Huang, Tainan City (TW); Bin Hu, Chandler, AZ (US); Yannan Liang, Gilbert, AZ (US); Hong Piao, Gilbert, AZ (US)

(21) Appl. No.: 17/875,458

(22) Filed: Jul. 28, 2022

Related U.S. Application Data
(60) Provisional application No. 63/229,745, filed on Aug. 5, 2021.

(51) Int. Cl. C09G 1/04; H01L 21/321

(52) U.S. Cl. CPC C09G 1/04; H01L 21/3212

(57) ABSTRACT

This disclosure relates to a composition that includes at least one first ruthenium removal rate enhancer; at least one copper removal rate inhibitor; at least one low-k removal rate inhibitor; and an aqueous solvent.

### CROSS-REFERENCE TO RELATED APPLICATION

The present application claims priority to U.S. Provisional Application Ser. No. 63/229,745, filed on Aug. 5, 2021, the contents of which are hereby incorporated by reference in their entirety.

### BACKGROUND

The semiconductor industry is continually driven to improve chip performance by further miniaturization of devices through process and integration innovations. Chemical Mechanical Polishing/Planarization (CMP) is a powerful technology as it makes many complex integration schemes at the transistor level possible, thereby facilitating increased chip density.

CMP is a process used to planarize/flatten a wafer surface by removing material using abrasion-based physical processes concurrently with surface-based chemical reactions. In general, a CMP process involves applying CMP slurry (e.g., an aqueous chemical formulation) to a wafer surface while contacting the wafer surface with a polishing pad and moving the polishing pad in relation to the wafer. CMP slurries typically include an abrasive component and dissolved chemical components, which can vary significantly depending upon the materials present on the wafer (e.g., metals, metal oxides, metal nitrides, dielectric materials such as silicon oxide, silicon nitride, etc.) that will be interacting with the slurry and the polishing pad during the CMP process.

After CMP processing, the polished wafers are usually rinsed with deionized water, commonly referred to as high pressure rinsing, to terminate any chemical reactions and remove water miscible components (e.g., pH adjusters, organic components, and oxidants) and byproducts (e.g., ionic metals removed during CMP or pad debris) left on the polished wafer after the CMP processing step. However, even after the deionized water rinse, a variety of contaminants may remain on the surface of the polished wafer. Contaminants may include, for example, particulate abrasive from the CMP slurry, organic residue from the pad or slurry components, and material removed from the wafer during the CMP process. If left on the surface of the polished wafer, these contaminants may lead to failures during further wafer processing steps and/or to diminished device performance. Thus, the contaminants need to be effectively removed so that the polished wafer may predictably undergo further processing and/or to achieve optimal device performance.

Commonly, the process of removing these post-polishing contaminants or residues on the wafer surface after CMP (and the deionized water rinse) is performed with post-CMP (P-CMP) cleaning solutions. P-CMP cleaning solutions are applied to the polished wafer using a brush scrubber or a spin rinse dry apparatus (i.e., the wafer is removed from the CMP polishing tool and transferred to a different apparatus for P-CMP cleaning). Nonetheless, with the complex integration schemes and scaling down of size in advanced node semiconductor manufacturing, it has been increasingly noticed that traditional P-CMP cleaning is insufficient to adequately remove contaminants from the polished wafer.

### SUMMARY

In semiconductor chip manufacturing, defectivity on the wafer surface is the key to the yield of the wafers which determines the top and bottom line of chip companies globally. A typical wafer goes through about 1000 processes before chips are made and the individual dies are cut from the wafer. At each of these processes, the defectivity is monitored pre- & post-process. CMP is an important step in chip manufacturing. However, the CMP steps introduce a significant amount of defects to the wafers. As mentioned above, the conventional workflow, shown in FIG. 1, has proven inadequate at removing contaminants in advanced node semiconductor manufacturing. The present disclosure relates to polisher rinse compositions and methods for processing a polished substrate on the polishing tool itself (i.e., without removing the polished substrate from the polishing tool). A general workflow for a method using polisher rinse compositions according to this disclosure is shown in FIG. 2 and will be described in detail later in this disclosure. Thus, the present disclosure discusses polisher rinse compositions and methods which not only reduce wafer defects but also provide various other electrochemical attributes that are critical for chip manufacturing.

In one aspect, this disclosure features a composition that includes at least one first ruthenium removal rate enhancer; at least one copper removal rate inhibitor; at least one low-k removal rate inhibitor; and an aqueous solvent, in which the composition has a pH of from about 7 to about 14.

In another aspect, the disclosure features a composition that includes at least one acid or a salt thereof selected from the group consisting of nitric acid, nitrate salts, phosphoric acid, phosphate salts, thiocyanic acid, thiocyanate salts, sulfuric acid, sulfate salts, hydrogen halides, and halide salts; at least one heterocyclic compound selected from the group consisting of an azole, a purine, and a pyrimidine; at least one non-ionic surfactant; and an aqueous solvent, in which the composition has a pH of from about 7 to about 14.

In still another aspect, this disclosure features a method that includes applying the composition disclosed (e.g., a polisher rinse composition) to a polished substrate containing ruthenium or an alloy thereof on a surface of the substrate in a polishing tool; and bringing a pad into contact with the surface of the substrate and moving the pad in relation to the substrate to form a rinse polished substrate.

This summary is provided to introduce a selection of concepts that are further described below in the detailed description. This summary is not intended to identify key or essential features of the claimed subject matter, nor is it intended to be used as an aid in limiting the scope of the claimed subject matter.

### DESCRIPTION OF DRAWINGS

FIG. 1 is a workflow diagram for a conventional CMP and P-CMP clean process.

FIG. 2 is a workflow diagram for an example of CMP and, optionally, a P-CMP clean process that incorporates a rinse composition described herein after the CMP process.

### DETAILED DESCRIPTION

Embodiments disclosed herein relate generally to rinse compositions and methods of using said compositions to wash substrates while the substrates are still on a polishing tool (e.g., a CMP polishing tool). In particular, the rinse compositions can be used to clean substrates directly after a CMP process and these rinse compositions are sometimes referred to herein as “rinse polish”, “buff chemical”, or “polisher rinse” compositions. In addition, the rinse compositions described herein can also find use in removing residue and/or contaminants from a substrate surface after an etching process, after an ashing process, after a plating process, or even in a conventional P-CMP cleaning process (i.e., one that takes place using a separate apparatus from the polishing tool).

As defined herein, residue and/or contaminants can include components present in a CMP polishing composition that has been used to polish the substrate to be cleaned (e.g., abrasives, molecular components, polymers, acids, bases, salts, surfactants, etc.), compounds produced during the CMP process as a result of chemical reactions between the substrate and the polishing composition and/or between components of the polishing composition, polishing pad debris particles (e.g., particles of a polymeric pad), polishing byproducts, organic or inorganic residues (e.g., those from a CMP slurry or CMP pad), substrate (or wafer) particles liberated during the CMP process, and/or any other removable materials that are known to deposit on a substrate after a CMP process.

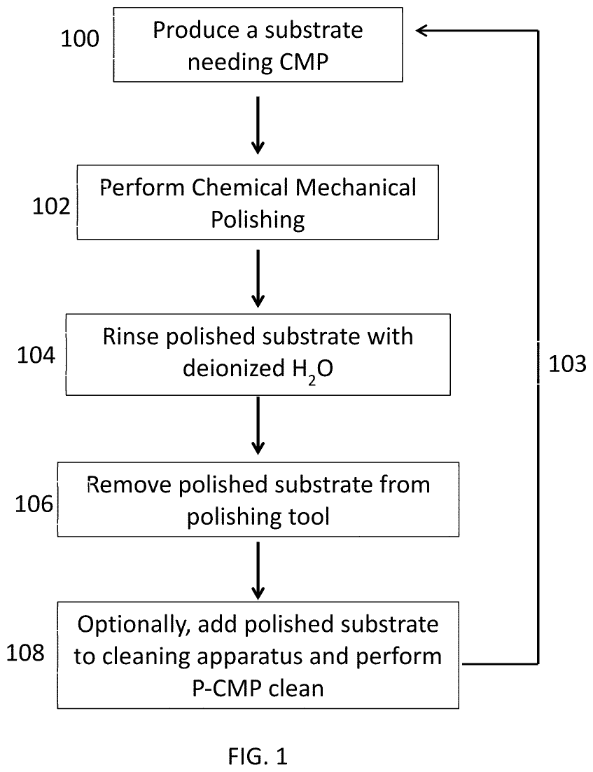

FIG. 1 is a workflow diagram for a conventional CMP and P-CMP clean process. The CMP step is typically performed in a polishing tool, which includes at least a polishing chamber (which includes polishing pads, polishing platens, and polishing heads), a cleaning chamber, and a drying chamber. In step 100, a substrate needing CMP is produced, e.g., after lithography and/or a material is deposited on the substrate. For example, the material that is deposited can be a metal or a dielectric material and the substrate can be a silicon wafer. In step 102, chemical mechanical planarization is performed in a polishing chamber of a polishing tool. For example, a wafer can be delivered to a polishing head in the polishing chamber and attached to the polishing head by vacuum before the CMP. The head can then bring the wafer to press onto a polishing pad, rotate the wafer, and apply an appropriate pressure to the wafer during CMP. CMP is performed in order to remove unnecessary deposited material and planarize the surface of the deposited material on the substrate. After the CMP, in step 104 the polished substrate (where “polished substrate” is defined as a substrate that has been polished using a CMP method) is rinsed with deionized (DI) water. This step is commonly believed to assist in washing/cleaning debris and residue left on the polished substrate and takes place in the polishing chamber of the polishing tool using milder polishing conditions (e.g., less downforce and rotational speed) directly after the polishing. However, without wishing to be bound by theory, it is believed that the drastic pH change from a CMP polishing composition (which can be highly acidic or highly alkaline) to DI water can cause some adverse chemistry to occur that can effectively cause a portion of the debris/residue to stick more tightly to the polished substrate surface. Subsequently, the now more tightly bound debris/residue are much more difficult to remove with a conventional P-CMP cleaning process once the polished substrate is removed from the polishing tool in step 106, transferred to a conventional P-CMP cleaning apparatus and cleaned in step 108. Optionally, after the conventional P-CMP cleaning in step 108, the polished substrate can be subjected to workflow 103 during which steps 100, 102, 104, 106, and 108 are repeated. If no further lithography/deposition and CMP is desired after step 108, the polished substrate can be used in a subsequent semiconductor manufacturing process.

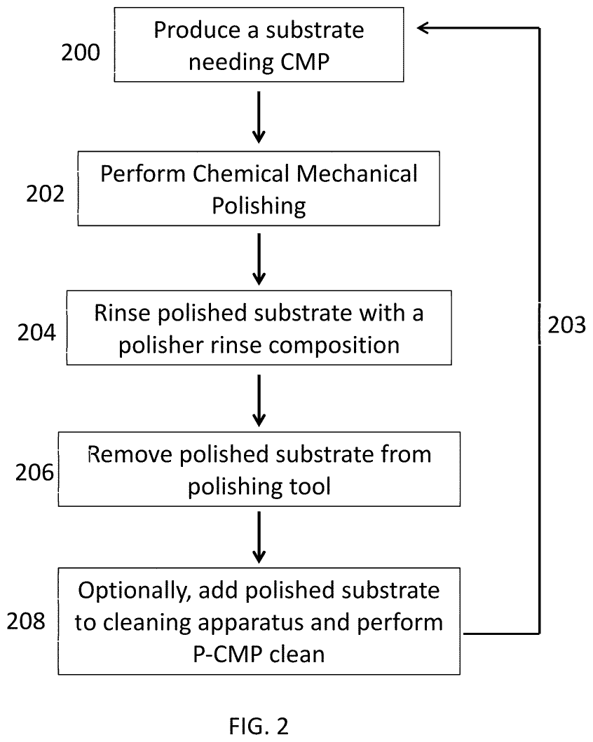

FIG. 2 is a workflow diagram for an example of a process of the present invention, which incorporates a polisher rinse composition described herein between the CMP process and an optional P-CMP process. In step 200, a substrate needing CMP is produced, e.g., after lithography and/or deposition of a material on the substrate. In step 202, chemical mechanical planarization is performed in a polishing chamber of a polishing tool. After the CMP, in step 204, the polished substrate is rinsed with a polisher rinse composition as disclosed herein. In some embodiments, a brief (e.g., a few seconds or less) DI water rinse is applied to the polished substrate directly after CMP. This brief DI water rinse can purge the equipment lines, the pad, and the polished substrate of any remaining CMP polishing composition and wash away any large debris. As mentioned herein, the process in step 204 is also referred to as a “rinse polishing process”. The rinse in step 204 is performed on the polished substrate while the polished substrate is still located in the polishing chamber of the polishing tool (e.g., attached to a polishing head in the polishing chamber and facing a polishing pad). In some embodiments, in step 204, the polisher rinse composition is applied to the polished substrate at the same time that the polishing pad is in contact with the polished substrate and moving in relation to the substrate (i.e., the polishing pad is being used as it would be during a CMP process). One of the main differences between a CMP step and the rinse polish in step 204 is that the polisher rinse composition being applied to the substrate includes substantially no abrasive particles, or a much smaller amount of abrasive particles (detailed below), than a CMP slurry composition would include. Thus, the material removed from the polished substrate in step 204 is primarily the debris/residue from the polishing step and not the deposited substrate material that is intended to be maintained on the polished substrate.

In some embodiments, the polisher rinse composition used on the polished substrate has a difference in pH value that is no more than about ±3 (e.g., no more than about ±2.5, no more than about ±2, no more than about ±1.5, no more than about ±1, or no more than about ±0.5) from the pH value of the CMP composition used to polish the polished substrate. In some embodiments, the pH value of the polisher rinse composition can be acidic if the pH value of the CMP composition used to polish the substrate was acidic or the pH value of the polisher rinse composition can be basic if the pH value of the CMP composition used to polish the substrate was basic. In some embodiments, the pH value of the polisher rinse composition can be substantially the same as the pH value of the CMP polishing slurry used to polish the polished substrate. Without being bound by theory, it is believed that the use of a similar pH value for the CMP polish composition and the polisher rinse composition can result in more effective removal of the debris/residue left behind on the polished substrate than using simply DI water as a rinse.

The rinsed polished substrate is removed from the polishing tool in step 206 and transferred to a cleaning apparatus for the conventional P-CMP cleaning in step 208. Optionally, after the conventional P-CMP cleaning in step 208, the polished substrate can be subjected to workflow 203 during which steps 200, 202, 204, 206, and 208 are repeated. If no further deposition and CMP is desired after step 208, the polished substrate can be used in a subsequent semiconductor manufacturing process.

In one or more embodiments, a polisher rinse composition described herein includes at least one first ruthenium removal rate enhancer, optionally at least one second ruthenium removal rate enhancer different from the first ruthenium removal rate enhancer, optionally at least one metal oxide remover, at least one copper removal rate inhibitor, at least one low-k removal rate inhibitor, and an aqueous solvent. In one or more embodiments, a polisher rinse composition of the present disclosure can include from about 0.001% to about 10% by weight of the at least one first ruthenium removal rate enhancer, optionally from about 0.001% to about 10% by weight of the at least one second ruthenium removal rate enhancer, optionally from about 0.01% to about 40% by weight of the at least one metal oxide remover, from about 0.001% to about 10% by weight of the at least one copper removal rate inhibitor, from about 0.001% to about 10% by weight of the at least one low-k removal rate inhibitor, and the remaining percent by weight (e.g., from about 20% to about 99.99% by weight) of aqueous solvent (e.g., deionized water).

In one or more embodiments, the present disclosure provides for a concentrated polisher rinse composition that can be diluted with water to obtain a point-of-use (POU) composition by up to a factor of 5, or up to a factor of 10, or up to a factor of 20, or up to a factor of 50, or up to a factor of 100, or up to a factor or 200, or up to a factor of 400, or up to a factor of 800, or up to a factor of 1000. In other embodiments, the present disclosure provides a point-of-use (POU) polisher rinse composition that can be used directly for washing substrate surfaces on a polishing tool.

In one or more embodiments, a POU polisher rinse composition can include from about 0.001% to about 1% by weight of the at least one first ruthenium removal rate enhancer, optionally from about 0.001% to about 1% by weight of the at least one second ruthenium removal rate enhancer, optionally from about 0.01% to about 10% by weight of the at least one metal oxide remover, from about 0.001% to about 1% by weight of the at least one copper removal rate inhibitor, from about 0.001% to about 1% by weight of the at least one low-k removal rate inhibitor, and the remaining percent by weight (e.g., from about 80% to about 99.99% by weight) of aqueous solvent (e.g., deionized water).

In one or more embodiments, a concentrated polisher rinse composition can include from about 0.01% to about 10% by weight of the at least one first ruthenium removal rate enhancer, optionally from about 0.01% to about 10% by weight of the at least one second ruthenium removal rate enhancer, optionally from about 0.1% to about 40% by weight of the at least one metal oxide remover, from about 0.01% to about 10% by weight of the at least one copper removal rate inhibitor, from about 0.01% to about 10% by weight of the at least one low-k removal rate inhibitor, and the remaining percent by weight (e.g., from about 20% to about 99.99% by weight) of aqueous solvent (e.g., deionized water).

In one or more embodiments, the polisher rinse composition described herein can include at least one (e.g., two or three) first ruthenium removal rate enhancer (e.g., an organic acid, an inorganic acid, or a salt thereof). In some embodiments, the at least one first ruthenium removal rate enhancer can be selected from the group consisting of nitric acid, nitrate salts, phosphoric acid, phosphate salts, thiocyanic acid, thiocyanate salts, sulfuric acid, sulfate salts, hydrogen halides, and halide salts. In some embodiments, the first ruthenium removal rate enhancer is selected from the group consisting of nitric acid, lithium nitrate, sodium nitrate, potassium nitrate, rubidium nitrate, cesium nitrate, barium nitrate, calcium nitrate, ammonium nitrate, phosphoric acid, lithium phosphate, sodium phosphate, potassium phosphate, rubidium phosphate, cesium phosphate, calcium phosphate, magnesium phosphate, ammonium phosphate, sulfuric acid, lithium sulfate, sodium sulfate, potassium sulfate, rubidium sulfate, cesium sulfate, barium sulfate, calcium sulfate, ammonium sulfate, hydrofluoric acid, hydrochloric acid, hydrobromic acid, hydrogen iodide, ammonium fluoride, ammonium bromide, sodium fluoride, potassium fluoride, rubidium fluoride, cesium fluoride, sodium chloride, potassium chloride, rubidium chloride, cesium chloride, thiocyanic acid, ammonium thiocyanate, potassium thiocyanate, sodium thiocyanate, and mixtures thereof. In some embodiments, the first ruthenium removal rate enhancer is nitric acid or a nitrate salt. Without being bound by theory, it is believed that the first ruthenium removal rate enhancer (e.g., those including a nitrate anion) has a strong affinity for oxidized ruthenium (which may be a residue left behind after a polishing process on a ruthenium containing wafer) and also forms water soluble Ru-containing complexes (e.g., Ru-nitrate complexes).

In one or more embodiments, the first ruthenium removal rate enhancer is included in the polisher rinse composition in an amount from about 0.001% to about 10% by weight of the composition. For example, the first ruthenium removal rate enhancer can be at least about 0.001% (e.g., at least about 0.002%, at least about 0.005%, at least about 0.01%, at least about 0.02%, at least about 0.05%, at least about 0.1%, at least about 0.2%, or at least about 0.5%) by weight to at most about 10% (e.g., at most about 5%, at most about 2%, at most about 1%, at most about 0.5%, at most about 0.2%, at most about 0.1%, at most about 0.05%, or at most about 0.02%) by weight of the polisher rinse composition described herein.

In one or more embodiments, the polisher rinse composition described herein can optionally include at least one (e.g., two or three) second ruthenium removal rate enhancer. In some embodiments, the composition includes both a first ruthenium removal rate enhancer and a second ruthenium removal rate enhancer and they are chemically distinct compounds. In one or more embodiments, the second ruthenium removal rate enhancer is a complexing agent that includes at least two (e.g., three or four) nitrogen atoms. For example, the second ruthenium removal rate enhancer can be a polyamine optionally containing one or more (e.g., two or three) acid groups. In one or more embodiments, the second ruthenium removal rate enhancer is selected from the group consisting of ethylenediamine, N,N,N′,N″,N″-pentamethyldiethylenetriamine, ethylenediaminetetraacetic acid, diethylenetriaminepentaacetic acid, aminotris(methylenephosphonic) acid, ethylenediamine tetra(methylene phosphonic acid), 1,2-diaminocyclohexanetetraacetic acid monohydrate, diethylenetriamine, triethylenetetramine, tetraethylenepentamine, aminoethylethanolamine, N,N,N′,N″,N″-pentamethyldiethylenetriamine, their derivatives, salts, and mixture thereof. Without being bound by theory, it is believed that the second ruthenium removal rate enhancer has a synergistic effect with the first ruthenium removal rate enhancer as a composition containing both enhancers is capable of removing oxidized ruthenium from a previously polished substrate more effectively than the addition effects of two compositions each containing one enhancer alone.

In one or more embodiments, the second ruthenium removal rate enhancer is included in the polisher rinse composition in an amount from about 0.001% to about 10% by weight of the composition. For example, the second ruthenium removal rate enhancer can be at least about 0.001% (e.g., at least about 0.002%, at least about 0.005%, at least about 0.01%, at least about 0.02%, at least about 0.05%, at least about 0.1%, at least about 0.2%, or at least about 0.5%) by weight to at most about 10% (e.g., at most about 5%, at most about 2%, at most about 1%, at most about 0.5%, at most about 0.2%, at most about 0.1%, at most about 0.05%, or at most about 0.02%) by weight of the polisher rinse composition described herein.

In one or more embodiments, the polisher rinse composition described herein can optionally include at least one (e.g., two or three) metal oxide remover. In one or more embodiments, the metal oxide remover includes nitrogen and at least one (e.g., both) of oxygen or sulfur. For example, the metal oxide remover can be an aminoalcohol or an amino acid. In one or more embodiments, the metal oxide remover is selected from the group consisting of ethanolamine, diethanolamine, triethanolamine, 2-amino-2-methyl-1-propanol, 2-amino methyl-1,3-propanediol, 2-dimethylamino-2-methylpropanol, tris(hydroxymethyl)aminomethane, 2-amino-2-ethyl-1,3-propanediol, 3-amino-4-octanol, aminopropyldiethanolamine, 2-[(3-aminopropyl)methylamino]ethanol, 2-(2-aminoethoxy)ethanol, 2-(3-aminopropylamino)ethanol, 2-dimethylaminoethanol, cysteamine, L-cysteine, N-acetyl-L-cysteine, and mixtures thereof. Without being bound by theory, it is believed that the metal oxide remover facilitates the dissolution and removal of any abrasive residue from the polished substrate.

In some embodiments, the metal oxide remover is in an amount of from about 0.01% to about 40% by weight of the polisher rinse composition described herein. For example, the metal oxide remover can be at least about 0.01% (e.g., at least about 0.02%, at least about 0.05%, at least about 0.1%, at least about 0.2%, at least about 0.5%, at least about 1%, at least about 2%, or at least about 5%) by weight to at most about 40% (e.g., at most about 20%, at most about 10%, at most about 5%, at most about 2%, at most about 1%, at most about 0.5%, at most about 0.2%, at most about 0.1%, at most about 0.05%, or at most about 0.02%) by weight of the polisher rinse composition described herein. In some embodiments, the polisher rinse composition described herein is substantially free of the metal oxide remover.

In one or more embodiments, the polisher rinse composition described herein can include at least one (e.g., two or three) copper removal rate inhibitor. In one or more embodiments, the copper removal rate inhibitor is a heterocyclic compound, such as a heterocyclic compound containing at least two (e.g., three or four) ring nitrogen atoms. In one or more embodiments, the copper removal rate inhibitor is an azole, such as a triazole (e.g., a benzotriazole), a tetrazole, a pyrazole, an imidazole, or a thiadiazole, each of which is optionally substituted with one or more substituents (e.g., halo, amino, C₁-C₁₀ alkyl, C₁-C₁₀ arylalkyl, C₁-C₁₀ haloalkyl, or aryl). In one or more embodiments, the copper removal rate inhibitor is a purine (e.g., 9H-purine, xanthine, hypoxanthine, guanine, and isoguanine) or a pyrimidine (e.g., cytosine, thymine, and uracil). In one or more embodiments, the copper removal rate inhibitor is selected from the group consisting of tetrazole, benzotriazole, tolyltriazole, methyl benzotriazole (e.g., 1-methyl benzotriazole, 4-methyl benzotriazole, and 5-methyl benzotriazole), ethyl benzotriazole (e.g., 1-ethyl benzotriazole), propyl benzotriazole (e.g., 1-propyl benzotriazole), butyl benzotriazole (e.g., 1-butyl benzotriazole and 5-butyl benzotriazole), pentyl benzotriazole (e.g., 1-pentyl benzotriazole), hexyl benzotriazole (e.g., 1-hexyl benzotriazole and 5-hexyl benzotriazole), dimethyl benzotriazole (e.g., 5,6-dimethyl benzotriazole), chloro benzotriazole (e.g., 5-chloro benzotriazole), dichloro benzotriazole (e.g., 5,6-dichloro benzotriazole), chloromethyl benzotriazole (e.g., 1-(chloromethyl)-1-H-benzotriazole), chloroethyl benzotriazole, phenyl benzotriazole, benzyl benzotriazole, aminotriazole, aminobenzimidazole, pyrazole, imidazole, aminotetrazole, adenine, xanthine, cytosine, thymine, uracil, 9H-purine, guanine, isoguanine, hypoxanthine, benzimidazole, thiabendazole, 1,2,3-triazole, 1,2,4-triazole, 1-hydroxybenzotriazole, 2-methylbenzothiazole, 2-aminobenzimidazole, 2-amino-5-ethyl-1,3,4-thiadiazole, 3,5-diamino-1,2,4-triazole, 3-amino-5-methylpyrazole, 4-amino-4H-1,2,4-triazole, and combinations thereof.

In one or more embodiments, the copper removal rate inhibitor is included in the polisher rinse composition in an amount from about 0.001% to about 10% by weight of the composition. For example, the copper removal rate inhibitor can be at least about 0.001% (e.g., at least about 0.002%, at least about 0.004%, at least about 0.006%, at least about 0.008%, at least about 0.01%, at least about 0.02%, at least about 0.04%, at least about 0.06%, or at least about 0.08%) by weight to at most about 10% (e.g., at most about 8%, at most about 6%, at most about 4%, at most about 2%, at most about 1%, at most about 0.8%, at most about 0.6%, or at most about 0.4%) by weight of the polisher rinse composition described herein.

In one or more embodiments, the polisher rinse composition described herein can include at least one (e.g., two or three) low-k removal rate inhibitor. In one or more embodiments, the low-k removal rate inhibitor is a non-ionic surfactant. In one or more embodiments, the low-k removal rate inhibitor is selected from the group consisting of alcohol alkoxylates (e.g., ethylene glycol), alkylphenol alkoxylates (e.g., 4-nonylphenyl-polyethylene glycol), tristyrylphenol alkoxylates (e.g., tristyrylphenol ethoxylate), sorbitan ester alkoxylates (e.g., polysorbates), polyalkoxylates (e.g., polyethylene glycol), polyalkylene oxide block copolymers (e.g., C₁₂-C₁₄ tert-alkylamines ethoxylated propoxylated), alkoxylated diamines, and mixtures thereof.

In one or more embodiments, the low-k removal rate inhibitor is included in the polisher rinse composition in an amount from about 0.001% to about 10% by weight of the composition. For example, the low-k removal rate inhibitor can be at least about 0.001% (e.g., at least about 0.002%, at least about 0.004%, at least about 0.006%, at least about 0.008%, at least about 0.01%, at least about 0.02%, at least about 0.04%, at least about 0.06%, or at least about 0.08%) by weight to at most about 10% (e.g., at most about 8%, at most about 6%, at most about 4%, at most about 2%, at most about 1%, at most about 0.8%, at most about 0.6%, or at most about 0.4%) by weight of the polisher rinse composition described herein.

An optional oxidizer can be added when diluting a concentrated polisher rinse composition to form a POU slurry. The oxidizer can be selected from the group consisting of hydrogen peroxide, ammonium persulfate, silver nitrate (AgNO₃), ferric nitrates or chlorides, per acids or salts, ozone water, potassium ferricyanide, potassium dichromate, potassium iodate, potassium bromate, potassium periodate, periodic acid, vanadium trioxide, hypochlorous acid, sodium hypochlorite, potassium hypochlorite, calcium hypochlorite, magnesium hypochlorite, potassium permanganate, other inorganic or organic peroxides, and mixtures thereof. In one embodiment, the oxidizer is hydrogen peroxide.

In some embodiments, the oxidizer is in an amount of from at least about 0.05% (e.g., at least about 0.1%, at least about 0.2%, at least about 0.4%, at least about 0.5%, at least about 1%, at least about 1.5%, at least about 2%, at least about 2.5%, at least about 3%, at least about 3.5%, at least about 4%, or at least about 4.5%) by weight to at most about 5% (e.g., at most about 4.5%, at most about 4%, at most about 3.5%, at most about 3%, at most about 2.5%, at most about 2%, at most about 1.5%, at most about 1%, at most about 0.5%, or at most about 0.1%) by weight of the polisher rinse composition described herein. In some embodiments, without wishing to be bound by theory, it is believed that the oxidizer can help remove metal films by forming a metal complex with the chelating agent so that the metal can be removed during the CMP process. In some embodiments, without wishing to be bound by theory, it is believed that the oxidizer can help passivate a metal surface by forming an oxide film that can increase the corrosion resistance of the metal film. In some embodiments, the oxidizer may reduce the shelf life of a polisher rinse composition. In such embodiments, the oxidizer can be added to the polisher rinse composition at the point of use right before a rinse polishing process.

In some embodiments, the pH value of the polisher rinse composition described herein can range from at least about 7 (e.g., at least about 7.5, at least about 8, at least about 8.5, at least about 9, at least about 9.5, at least about 10, at least about 10.5, at least about 11, or at least about 11.5) to at most about 14 (e.g., at most about 13.5, at most about 13, at most about 12.5, at most about 12, at most about 11.5, at most about 11, at most about 10.5, at most about 10, or at most about 9.5). In some embodiments, the pH value of the polisher rinse composition described herein can range from at least about 1 (e.g., at least about 1.5, at least about 2, at least about 2.5, at least about 3, at least about 4.5, at least about 5, at least about 5.5, at least about 6, or at least about 6.5) to at most about 7 (e.g., at most about 6.5, at most about 6, at most about 5.5, at most about 5, at most about 4.5, at most about 4, at most about 3.5, at most about 3, or at most about 2.5).

In one or more embodiments, the polisher rinse composition described herein can optionally include a relatively small amount of abrasive particles. In some embodiments, the abrasive particles can include silica, ceria, alumina, titania, and zirconia abrasives. In some embodiments, the abrasive particles can include non-ionic abrasives, surface modified abrasives, or negatively/positively charged abrasives. In some embodiments, the polisher rinse composition can include abrasive particles in an amount of from at least 0.001% (e.g., at least about 0.005%, at least about 0.01%, at least about 0.05%, or at least about 0.1%) by weight to at most about 0.2% (e.g., at most about 0.15%, at most about 0.1%, at most about 0.05%, or at most about 0.01%) by weight of the polisher rinse composition described herein. In some embodiments, the polisher rinse composition described herein can be substantially free of any abrasive particle.

In one or more embodiments, the composition is substantially free of abrasive particles. As used herein, an ingredient that is “substantially free” from a composition refers to an ingredient that is not intentionally added into the cleaning composition. In some embodiments, the composition described herein can have at most about 2000 ppm (e.g., at most about 1000 ppm, at most about 500 ppm, at most about 250 ppm, at most about 100 ppm, at most about 50 ppm, at most about 10 ppm, or at most about 1 ppm) of abrasive particles. In some embodiments, the composition described herein can be completely free of abrasive particles.

In one or more embodiments, the polisher rinse composition described herein can be substantially free of one or more of certain ingredients, such as organic solvents, pH adjusting agents, quaternary ammonium compounds (e.g., salts such as tetraalkylammonium salts or hydroxides such as tetraalkylammonium hydroxides), alkali bases (such as alkali hydroxides), fluorine containing compounds (e.g., fluoride compounds or fluorinated compounds (e.g., fluorinated polymers/surfactants)), silicon containing compounds such as silanes (e.g., alkoxysilanes), nitrogen-containing compounds (e.g., amino acids, amines, imines (e.g., amidines such as 1,8-diazabicyclo[5.4.0]-7-undecene (DBU) and 1,5-diazabicyclo[4.3.0]non-5-ene (DBN)), amides, or imides), salts (e.g., halide salts or metal salts), polymers (e.g., non-ionic, cationic, or anionic polymers), surfactants (e.g., cationic surfactants, anionic surfactants, or non-ionic surfactants), plasticizers, oxidizing agents (e.g., H₂O₂ and periodic acid), corrosion inhibitors (e.g., azole or non-azole corrosion inhibitors), electrolytes (e.g., polyelectrolytes), and/or abrasives (e.g., ceria abrasives, non-ionic abrasives, surface modified abrasives, negatively/positively charged abrasives, or ceramic abrasive composites). The halide salts that can be excluded from the compositions include alkali metal halides (e.g., sodium halides or potassium halides) or ammonium halides (e.g., ammonium chloride), and can be fluorides, chlorides, bromides, or iodides. As used herein, an ingredient that is “substantially free” from a polisher rinse composition refers to an ingredient that is not intentionally added into the composition. In some embodiments, the polisher rinse composition described herein can have at most about 2000 ppm (e.g., at most about 1000 ppm, at most about 500 ppm, at most about 250 ppm, at most about 100 ppm, at most about 50 ppm, at most about 10 ppm, or at most about 1 ppm) of one or more of the above ingredients. In some embodiments, the polisher rinse composition described herein can be completely free of one or more of the above ingredients.

As applied to polisher rinse operations, the polisher rinse compositions described herein are usefully employed to remove contaminants present on a substrate surface directly after a CMP processing step while the polished substrate is still located within the polishing chamber of the polishing tool. In one or more embodiments, the contaminants can be at least one selected from the group consisting of abrasives, particles, organic residues, polishing byproducts, slurry byproducts, slurry induced organic residues, and inorganic polished substrate residues. In one or more embodiments, the polisher rinse compositions of the present disclosure can be employed to remove organic residues containing organic particles which are insoluble in water and thus remain on the wafer surface post the CMP polishing step. Without being bound by theory, it is believed that the organic particles can be generated from CMP polishing composition components that deposit on a substrate surface after polishing and are insoluble and thus stick as contaminants on the wafer surface. The presence of the contaminants described above results in defect counts on the wafer surface. These defect counts, when analyzed on a defect measuring tool such as the AIT-XUV tool from KLA Tencor Company, provide the total defect count (TDC) that is a sum of all the individual defect counts. In one or more embodiments, the compositions described herein remove at least about 30% (e.g., at least about 50%, at least about 75%, at least about 80%, at least about 90%, at least about 95%, at least about 98%, at least about 99%, at least about 99.5%, at least about 99.9%) of the total defect count (TDC) remaining on a substrate surface after a polishing/CMP process.

In some embodiments, this disclosure features a method of rinse polishing a previously polished substrate (e.g., a wafer polished by a CMP composition). The method can include contacting, within a polishing tool, the polished substrate with a polisher rinse composition described herein. In some embodiments, the substrate described herein (e.g. a wafer) can include at least one material selected from the group consisting of tungsten, titanium nitride, silicon carbide, silicon oxide (e.g., TEOS), low-K and ultra low-k materials (e.g., doped silica and amorphous carbon), silicon nitride, copper, cobalt, ruthenium, molybdenum, and polysilicon on a substrate surface.

In rinse polishing operations, the polisher rinse composition can be applied to the polished substrate in the same way that a CMP composition would have been applied to the previously polished substrate (e.g., the polisher rinse composition is applied while the polished substrate is in contact with a polishing pad). In some embodiments, the conditions can be milder during a rinse polishing process than the conditions used during a CMP process. For example, the down force, rotational speed, or time in a rinse polishing process can be less than the same conditions used in the prior CMP process.

In some embodiments, the down force used in a rinse polishing process is from at least about 5% (e.g., at least about 10%, at least about 15%, at least about 20%, at least about 25%, at least about 30%, at least about 35%, at least about 40%, at least about 45%, at least about 50%, at least about 55%, at least about 60%, at least about 65%, at least about 70%, or at least about 75%) to at most about 90% (e.g., at most about 85%, at most about 80%, at most about 75%, at most about 70%, or at most about 65%) of the down force used in a CMP process (e.g., in a preceding CMP process). In one or more embodiments, the down force used in a CMP process is from about 1 psi to about 4 psi. In some embodiments, a polishing pad is brought into contact with the previously polished substrate, but substantially no down force is applied to the previously polished substrate during the rinse polishing process. In some embodiments, the down force used in a rinse polishing process is substantially the same as the down force used in the prior CMP operation.

In some embodiments, the rinse time used in a rinse polishing process is from at least about 10% (e.g., at least about 15%, at least about 20%, at least about 25%, at least about 30%, or at least about 35%) to at most about 50% (e.g., at most about 45%, at most about 40%, at most about 35%, at most about 30%, or at most about 25%) of the rinse time used in a CMP process (e.g., in a preceding CMP process). In one or more embodiments, the rinse time used in a CMP process is from about 2 seconds to about 20 seconds. In some embodiments, the time used in a rinse polishing process is substantially the same as the down force used in the prior CMP operation.

In some embodiments, the polisher rinse composition described herein can be used as a post-CMP cleaner in a post-CMP cleaning step 208 (i.e., a cleaning step that takes place on a cleaning apparatus different from the polishing tool). In post-CMP cleaning applications, the polisher rinse composition can be applied in any suitable manner to the substrate to be cleaned. For example, the composition can be used with a large variety of conventional cleaning tools and techniques (e.g., brush scrubbing, spin rinse dry, etc.). In some embodiments, a cleaning tool or apparatus suitable for a post-CMP cleaning process is a tool (e.g., a brush scrubber or a spin rinse dryer) without a polishing equipment (e.g., a polishing pad, a polishing platen, and/or a polishing head). In some embodiments, the substrate to be cleaned (e.g. a wafer) in the post CMP cleaning step can include at least one material selected from the group consisting of tungsten, titanium nitride, silicon carbide, silicon oxide (e.g., TEOS), silicon nitride, copper, cobalt, ruthenium, molybdenum, and polysilicon on a substrate surface.

In some embodiments, the method that uses a polisher rinse composition described herein can further include producing a semiconductor device from the substrate treated by the cleaning composition through one or more steps. For example, photolithography, ion implantation, dry/wet etching, plasma etching, deposition (e.g., PVD, CVD, ALD, ECD), wafer mounting, die cutting, packaging, and testing can be used to produce a semiconductor device from the substrate treated by the cleaning composition described herein.

The specific examples below are to be construed as merely illustrative, and not limitative of the remainder of the disclosure in any way whatsoever. Without further elaboration, it is believed that one skilled in the art can, based on the description herein, utilize the present invention to its fullest extent.

### Example 1

In these examples, the polishing was performed on 300 mm wafers using an AMAT Reflexion 300 mm CMP polisher with a Fujibo pad and a CMP slurry at a flow rate between 100 and 500 mL/min. The rinse polishing step was performed using the same pad and the same flow rate for 15 seconds following the CMP polishing. The rinse polishing step was performed using the same conditions as the preceding CMP polishing step except that the rinse polishing step used about 66% of the down force for about 25% of the time of the CMP polishing step.

Polisher rinse (PR) compositions 1-10 were evaluated in this Example using the procedures above after wafers were polished by a CMP polishing composition. At the point of use, an oxidizer was added to the CMP polishing composition and PR compositions 1-10. The formulations of the CMP polishing composition and PR compositions 1-10 (after the oxidizer was added) are summarized in Table 1 and their test results are summarized in Table 2. The defect counts obtained for the CMP polishing composition are those defects observed after a conventional DI water rinse (as detailed in the specification).

As can be seen in Tables 1 and 2, the use of a polisher rinse composition after a polishing step significantly reduced the total defect counts (TDC) observed on the polished wafer. Further, the inclusion of a metal oxide remover (as shown in PR compositions 7-10) led to largest reduction in TDC when compared with what was present on the originally polished wafer after a DI water rinse.

TABLE 1

| | CMP | PR | PR | PR | PR | PR | PR | PR | PR | PR | PR |
|---|---|---|---|---|---|---|---|---|---|---|---|
| | Polishing | Comp. | Comp. | Comp. | Comp. | Comp. | Comp. | Comp. | Comp. | Comp. | Comp. |
| | Comp. | 1 | 2 | 3 | 4 | 5 | 6 | 7 | 8 | 9 | 10 |
| First Cu | 3.5× | 3.5× | 3.5× | 3.5× | 1.0× | 9.25× | 9.25× | 9.25× | 9.25× | 9.25× | 9.25× |
| RRI/conc. | Cu | Cu | Cu | Cu | Cu | Cu | Cu | Cu | Cu | Cu | Cu |
| | RRI-1 | RRI-1 | RRI-1 | RRI-1 | RRI-1 | RRI-3 | RRI-4 | RRI-4 | RRI-4 | RRI-4 | RRI-4 |
| Second Cu | 1× | none | none | none | none | none | none | none | none | none | none |
| RRI/conc. | Cu | | | | | | | | | | |
| | RRI-2 | | | | | | | | | | |
| First Ru | 0.52× | 0.52× | 0.26× | 0.13× | 0.26× | 0.26× | 0.26× | 0.05× | 0.05× | 0.05× | 0.05× |
| RRE/conc. | Ru | Ru | Ru | Ru | Ru | Ru | Ru | Ru | Ru | Ru | Ru |
| | RRE-1 | RRE-1 | RRE-1 | RRE-1 | RRE-1 | RRE-1 | RRE-1 | RRE-1 | RRE-1 | RRE-1 | RRE-1 |
| Second Ru | 0.9× | 0.9× | 0.45× | 0.225× | 0.45× | 0.45× | 0.45× | 0.1× | 0.1× | 0.1× | 0.1× |
| RRE/conc. | Ru | Ru | Ru | Ru | Ru | Ru | Ru | Ru | Ru | Ru | Ru |
| | RRE-2 | RRE-2 | RRE-2 | RRE-2 | RRE-2 | RRE-2 | RRE-2 | RRE-2 | RRE-2 | RRE-2 | RRE-2 |
| First LK | 25× | 25× | 25× | 25× | 25× | 25× | 25× | 3× | 3× | 3× | 3× |
| RRI/conc. | LK | LK | LK | LK | LK | LK | LK | LK | LK | LK | LK |
| | RRI-1 | RRI-1 | RRI-1 | RRI-1 | RRI-1 | RRI-1 | RRI-1 | RRI-1 | RRI-1 | RRI-1 | RRI-1 |
| Second LK | 5× | none | none | none | none | none | none | none | none | none | none |
| RRI/conc. | LK | | | | | | | | | | |
| | RRI-2 | | | | | | | | | | |
| MOR/conc. | none | none | none | none | none | none | none | 50× | 50× | 50× | 10× |
| | | | | | | | | MOR1 | MOR2 | MOR3 | MOR2 |
| oxidizer/conc. | OX1/2× | OX1/2× | OX1/2× | OX1/2× | OX1/2× | OX1/2× | OX1/2× | OX1/1× | OX1/1× | OX1/1× | OX1/1× |
| Abrasive | 2 wt % | none | none | none | none | none | none | none | none | none | none |
| | Silica | | | | | | | | | | |
| POU pH | 9.5 | 9.5 | 9.5 | 9.5 | 9.5 | 9.5 | 9.5 | 9.6 | 9.6 | 9.6 | 9.6 |

Cu RRI = Copper removal rate inhibitor
Ru RRE = Ruthenium removal rate enhancer
LK RRI = low-k removal rate inhibitor
MOR = Metal oxide remover
POU = Point of Use

TABLE 2

| | | CMP | PR | PR | PR | PR | PR | PR | PR | PR | PR | PR |
|---|---|---|---|---|---|---|---|---|---|---|---|---|
| | | Polishing | Comp. | Comp. | Comp. | Comp. | Comp. | Comp. | Comp. | Comp. | Comp. | Comp. |
| | | Comp. | 1 | 2 | 3 | 4 | 5 | 6 | 7 | 8 | 9 | 10 |
| Defects | OR | 7 | 1 | 3 | 2 | 3 | 3 | 2 | 3 | 1 | 2 | 2 |
| | corrosion | 9 | 5 | 4 | 2 | 4 | 5 | 4 | 4 | 4 | 4 | 5 |
| | pit | | | | | | | | | | | |
| | scratch | 169 | 124 | 117 | 120 | 123 | 129 | 115 | 90 | 74 | 80 | 82 |
| | others | 3 | 2 | 2 | 3 | 3 | 2 | 2 | 2 | 1 | 2 | 1 |
| | TDC | 188 | 132 | 126 | 127 | 133 | 139 | 123 | 99 | 80 | 88 | 90 |

OR = Organic residue

### Example 2

Polisher rinse (PR) compositions 2 and 11-14 were evaluated in this Example for their ability to solubilize ruthenium oxide particles, which are believed to make up a portion of the defects found on polished substrates that include ruthenium. The test was performed by incubating 0.005 g of ruthenium oxide particles in the indicated polisher rinse composition at 25° C. for 2 minutes in an ultrasonic bath. A sample of the supernatant was then taken and ppb Ru measured via ICP-MS. The formulations of these PR compositions and their test results are summarized in Table 3.

TABLE 3

| | | PR Comp. 2 | PR Comp. 11 | PR Comp. 12 | PR Comp. 13 | PR Comp. 14 |
|---|---|---|---|---|---|---|
| Cu RRI/conc. | | 3.5× | 3.5× | 3.5× | 3.5× | 3.5× |
| | | Cu RRI-1 | Cu RRI-1 | Cu RRI-1 | Cu RRI-1 | Cu RRI-1 |
| First Ru RRE/conc. | | 0.26× | 0.26× | none | 0.52× | none |
| | | Ru RRE-1 | Ru RRE-1 | | Ru RRE-1 | |
| Second Ru RRE/conc. | | 0.45× | none | 0.45× | none | 0.9× |
| | | Ru RRE-2 | | Ru RRE-2 | | Ru RRE-2 |
| LK RRI/conc. | | 25× | 25× | 25× | 25× | 25× |
| | | LK RRI-1 | LK RRI-1 | LK RRI-1 | LK RRI-1 | LK RRI-1 |
| oxidizer/conc. | | OX1/2× | OX1/2× | OX1/2× | OX1/2× | OX1/2× |
| POU pH | | 9.5 | 9.5 | 9.5 | 9.5 | 9.5 |
| Metal Oxide | Ru Ox | 70 | 25 | 31 | 30 | 42 |
| Solubility (ppb) | | | | | | |

As shown in Table 3, PR Composition 2 (which contained both the first and second ruthenium removal rate enhancers) exhibited a ruthenium oxide removal rate higher than the sum of the ruthenium oxide removal rates of PR Composition 11 (which contained only the first ruthenium removal rate enhancer at the same amount as PR Composition 2) and PR Composition 12 or 14 (which contained only the second ruthenium removal rate enhancer). In addition, the above results show that PR Composition 2 (which contained both the first and second ruthenium removal rate enhancers) exhibited a ruthenium oxide removal rate higher than PR Composition 13 (which contained the first ruthenium removal rate enhancer in an amount twice of the amount of this component in PR Composition 2) and PR Composition 14 (which contained the second ruthenium removal rate enhancer in an amount twice of the amount of this component in PR Composition 2). The above results suggested that a combination of the first and second ruthenium removal rate enhancers exhibited a synergistic effect in removing oxidized ruthenium.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed is:

1. A composition, comprising:
at least one first ruthenium removal rate enhancer;
at least one copper removal rate inhibitor;
at least one low-k removal rate inhibitor; and
an aqueous solvent;
wherein the composition has a pH of from about 7 to about 14.

2. The composition of claim 1, wherein the at least one first ruthenium removal rate enhancer comprises an acid or a salt thereof selected from the group consisting of nitric acid, lithium nitrate, sodium nitrate, potassium nitrate, rubidium nitrate, cesium nitrate, barium nitrate, calcium nitrate, ammonium nitrate, phosphoric acid, lithium phosphate, sodium phosphate, potassium phosphate, rubidium phosphate, cesium phosphate, calcium phosphate, magnesium phosphate, ammonium phosphate, sulfuric acid, lithium sulfate, sodium sulfate, potassium sulfate, rubidium sulfate, cesium sulfate, barium sulfate, calcium sulfate, ammonium sulfate, hydrofluoric acid, hydrochloric acid, hydrobromic acid, hydrogen iodide, ammonium fluoride, ammonium bromide, sodium fluoride, potassium fluoride, rubidium fluoride, cesium fluoride, sodium chloride, potassium chloride, rubidium chloride, cesium chloride, thiocyanic acid, ammonium thiocyanate, potassium thiocyanate, sodium thiocyanate and mixtures thereof.

3. The composition of claim 1, wherein the at least one first ruthenium removal rate enhancer is in an amount of from about 0.001% to about 10% by weight of the composition.

4. The composition of claim 1, further comprising at least one second ruthenium removal rate enhancer chemically distinct from the first ruthenium removal rate enhancer.

5. The composition of claim 4, wherein the at least one second ruthenium removal rate enhancer is selected from the group consisting of ethylenediamine, N,N,N′,N″,N″-pentamethyldiethylenetriamine, ethylenediaminetetraacetic acid, diethylenetriaminepentaacetic acid, aminotris(methylenephosphonic) acid, ethylenediamine tetra(methylene phosphonic acid), 1,2-diaminocyclohexanetetraacetic acid monohydrate, diethylenetriamine, triethylenetetramine, tetraethylenepentamine, aminoethylethanolamine, N,N,N′,N″,N″-pentamethyldiethylenetriamine, and salts and mixtures thereof.

6. The composition of claim 4, wherein the at least one second ruthenium removal rate enhancer is in an amount of from about 0.001% to about 10% by weight of the composition.

7. The composition of claim 1, further comprising at least one metal oxide remover.

8. The composition of claim 7, wherein the at least one metal oxide remover is selected from the group consisting of ethanolamine, diethanolamine, triethanolamine, 2-amino-2-methyl-1-propanol, 2-amino-2-methyl-1,3-propanediol, 2-dimethylamino-2-methylpropanol, tris(hydroxymethyl)aminomethane, 2-amino-2-ethyl-1,3-propanediol, 3-amino-4-octanol, aminopropyldiethanolamine, 2-[(3-aminopropyl)methylamino]ethanol, 2-(2-aminoethoxy)ethanol, 2-(3-aminopropylamino)ethanol, 2-dimethylaminoethanol, cysteamine, L-cysteine, N-acetyl-L-cysteine, and mixture thereof.

9. The composition of claim 7, wherein the at least one metal oxide remover is in an amount of from about 0.01% to about 40% by weight of the composition.

10. The composition of claim 1, wherein the at least one copper removal rate inhibitor comprises an azole, a purine, or a pyrimidine.

11. The composition of claim 10, wherein the at least one copper removal rate inhibitor is selected from the group consisting of tetrazole, benzotriazole, tolyltriazole, 1-methyl benzotriazole, 4-methyl benzotriazole, 5-methyl benzotriazole, 1-ethyl benzotriazole, 1-propyl benzotriazole, 1-butyl benzotriazole, 5-butyl benzotriazole, 1-pentyl benzotriazole, 1-hexyl benzotriazole, 5-hexyl benzotriazole, 5,6-dimethyl benzotriazole, 5-chloro benzotriazole, 5,6-dichloro benzotriazole, 1-(chloromethyl)-1H-benzotriazole, chloroethyl benzotriazole, phenyl benzotriazole, benzyl benzotriazole, aminotriazole, aminobenzimidazole, pyrazole, imidazole, aminotetrazole, adenine, xanthine, cytosine, thymine, uracil, 9H-purine, guanine, isoguanine, hypoxanthine, benzimidazole, thiabendazole, 1,2,3-triazole, 1,2,4-triazole, 1-hydroxybenzotriazole, 2-methylbenzothiazole, 2-aminobenzimidazole, 2-amino-5-ethyl-1,3,4-thiadiazole, 3,5-diamino-1,2,4-triazole, 3-amino-5-methylpyrazole, 4-amino-4H-1,2,4-triazole, and combinations thereof.

12. The composition of claim 1, wherein the at least one copper removal rate inhibitor is in an amount of from about 0.001% to about 10% by weight of the composition.

13. The composition of claim 1, wherein the at least one low-k removal rate inhibitor is a non-ionic surfactant.

14. The composition of claim 1, wherein the low-k removal rate inhibitor is selected from the group consisting of alcohol alkoxylates, alkylphenol alkoxylates, tristyrylphenol alkoxylates, sorbitan ester alkoxylates, polyalkoxylates, polyalkylene oxide block copolymers, tetrahydroxy oligomers, alkoxylated diamines, and mixtures thereof.

15. The composition of claim 1, wherein the at least one low-k removal rate inhibitor is in an amount of from about 0.001% to about 10% by weight of the composition.

16. The composition of claim 1, wherein the pH is from 9 to 13.

17. The composition of claim 1, wherein the composition has at most about 0.2% by weight of abrasive particles.

18. The composition of claim 1, wherein the composition is substantially free of abrasive particles.

19. A composition, comprising:
at least one acid or a salt thereof selected from the group consisting of nitric acid, nitrate salts, phosphoric acid, phosphate salts, thiocyanic acid, thiocyanate salts, sulfuric acid, sulfate salts, hydrogen halides, and halide salts;
at least one heterocyclic compound selected from the group consisting of an azole, a purine, and a pyrimidine;
at least one non-ionic surfactant; and
an aqueous solvent;
wherein the composition has a pH of from about 7 to about 14.

20. The composition of claim 19, further comprising at least one compound comprising nitrogen and at least one of oxygen and sulfur.

21. A method, comprising:
applying the composition of claim 1 to a polished substrate comprising ruthenium or an alloy thereof on a surface of the substrate in a polishing tool; and
bringing a pad into contact with the surface of the substrate and moving the pad in relation to the substrate to form a rinse polished substrate.

22. The method of claim 21, further comprising removing the cleaned substrate from the polishing tool and performing a post-CMP cleaning to the cleaned rinse polished substrate in a cleaning tool.

23. The method of claim 21, further comprising forming a semiconductor device from the substrate.
